(19) United States
(12) Patent Application Publication
(10) Pub. No.: US 2019/0252243 A1
(43) Pub. Date: Aug. 15, 2019

(54) METHOD OF MANUFACTURING AIRBRIDGES FOR HIGH PERFORMANCE SEMICONDUCTOR DEVICE

(71) Applicant: DUET MICROELECTRONICS INC., Raritan, NJ (US)

(72) Inventors: Ali Badar Alamin Dow, Raritan, NJ (US); John Ueng-McHale, Raritan, NJ (US); David Osika, Raritan, NJ (US)

(73) Assignee: DUET MICROELECTRONICS INC., Raritan, NJ (US)

(21) Appl. No.: 16/263,269

(22) Filed: Jan. 31, 2019

Related U.S. Application Data
(60) Provisional application No. 62/629,383, filed on Feb. 12, 2018.

(51) Int. Cl. H01L 21/768; H01L 21/02; H01L 21/311; H01L 23/528; H01L 23/532; H01L 23/00

(52) U.S. Cl. CPC H01L 21/7682; H01L 21/02175; H01L 21/31111; H01L 21/02266; H01L 23/5329; H01L 23/564; H01L 23/528

(57) ABSTRACT

A structure and manufacturing process produce an airbridge for semiconductor devices and circuit applications. Magnesium oxide (MgO) is used to fabricate airbridges. The use of evaporated MgO allows for a thicker and strong airbridge structure, and increases the yield during the singulation of the fabricated devices and circuits. Using MgO as a sacrificial layer provides the flexibility for the sacrificial layer to be removed during the backend process, thereby avoiding any damage in the airbridge structures. In an alternative embodiment, some or all of the MgO can be retained in the airbridge structure, allowing for high density interconnects especially for ground connected interconnects.

### CROSS-REFERENCE TO RELATED APPLICATION

This application claims priority to U.S. Provisional Application No. 62/629,383, filed on Feb. 12, 2018, which is incorporated by reference in its entirety.

### BACKGROUND OF THE INVENTION

### 1. Field of the Invention

The present invention relates to semiconductor devices, and in particular to a method of manufacturing airbridges in semiconductor devices.

### 2. Description of Prior Art

Monolithic microwave integrated circuits (MMIC) fabricated on GaAs and/or InP in the prior art use multi-finger transistors that are interconnected to other components and ports within the MMIC by airbridge structures. An airbridge is defined as a three-dimensional wiring and protection structure used to connect multiple fabricated semiconductor components and circuits on a substrate to employ an isolation layer of an air gap or alternatively a thin film between the fabricated airbridge structure and the substrate. In addition to wiring multiple fabricated components and circuits on the substrate, the airbridge structure also protects the fabricated circuits and components from moisture, for example, semiconductor active devices such as transistors and diodes disposed below and covered by the airbridge.

Typically, a rectangular U-shape is a common cross-sectional shape of an airbridge, as is known in the prior art. The covered area below the airbridge can be extended by increasing the width or the length of the airbridge above the surface of the substrate, thus more surface area of the substrate can be protected from moisture. However, the existing manufacturing methods are very complex and involve some steps that deteriorate the electrical characteristics of semiconductor components such as transistors and diodes. Further, the technologies of the prior art cannot provide a reliable, robust manufacturing approach especially during the singulation process for the fabricated devices. Moreover, there are always yield and reliability issues associated with the manufacturing methods of the prior art. Hence, the existing manufacturing approaches have inherent design and process limitations especially in cases where large-area interconnects are required.

Airbridges or air gaps and methods of fabrication of such airbridges and air gaps in the prior art are described, for example, in U.S. Pat. Nos. 5,677,574 A, 5,783,864 A, 5,817,446 A, 5,959,337 A, 6,071,805 A, 6,281,585 B1, 6,433,431 B1, 6,472,719 B1, 6,498,070 B2, 6,734,094 B2, 6,812,810 B2, 6,867,125 B2, 7,202,153 B2, 7,227,212 B1, 7,285,839 B2, 7,504,699 B1, 7,545,552 B2, 7,812,451 B2, 8,440,538 B2, 8,962,443 B2, and 9,030,016 B2; as well as Patent Publication Nos. US 20050011673 A1 and US 20060138663 A1, each of which is incorporated herein in its entirety.

The fabrication process of an airbridge in the prior art involves multiple steps. The first step is to spin or deposit a sacrificial layer (e.g., a resist) over the electrical components and circuits on the substrate as described, e.g., in the Patent Publication No. US 20050011673 A1. The second step is to structure the conductive layer of the airbridge on this sacrificial layer and subsequently followed by removing the sacrificial layer. Due to wiring complexity to interconnect multiple semiconductor elements and components on the substrate as well as protecting the fabricated circuits from moisture, the covered area below the airbridge needs to be extended by increasing the width and/or the length of the airbridge above the surface of the substrate. However, increasing the width and/or the length of the airbridge, which eventually requires a corresponding increase in the width and/or the length of the airbridge-sacrificial layer, can cause some problems in the fabrication process.

A typical sacrificial layer in the prior art is made of a removable resist or polymer layer which must maintain good thickness uniformity and should withstand the subsequent second layer processing when the seed and airbridge conductive layers are deposited to prevent any movement so that seed metal damage is avoided. The sacrificial layer can be hard baked and/or electron cured. However, lithography alignment marks openings must be created, so they are visible after the seed metal deposition. Good thickness uniformity for the sacrificial layer with no retrograde profile is difficult to obtain when the resist is spun or deposited on the surface with via posts topology.

Moreover, wide area airbridge structures need some gaps in the mask to aid the removal of the sacrificial layer. However, complete removal of the resist is very difficult and always some resist will remain, for example, at the corners. One possible approach for preventing the sacrificial layer from being left in the corners of an airbridge is to increase the opening area under the airbridge. However, increasing the opening area under the airbridge requires an increase in the size of the airbridge itself which significantly reduces the strength of the airbridge, thus causing the airbridge to collapse during the removal of the sacrificial layer. Further, since the sacrificial layer is formed along the increased width and or length of the airbridge, it will be very difficult to remove the sacrificial layer from in between the airbridge and the substrate surface.

In addition, air can get trapped during the spin coat of the photoresist, producing air bubbles especially during the soft bake step. Pre-wetting the substrate can help to break the surface tension on the substrate. However, pre-wetting will not eliminate all bubbles. Since the deposition of the seed metal layer is performed under high vacuum, the sacrificial layer can shrink and damage the airbridge structure. Many classical manufacturing approaches in the prior art involve the deposition of silicon nitride as a protection layer. However, such deposition reduces the strength of the airbridge especially during the high vacuum deposition step of the seed layer. Furthermore, larger thin airbridges can easily rip, e.g., by air pressure during the singulation of the fabricated devices especially when the airbridges are close to the singulation streets.

Another possible approach in the prior art is to form a curved surface airbridge which is expected to prevent any sacrificial material from being left in the inner corners of the fabricated airbridge, as well as maintaining a good strength level of the airbridge, but there are many fabrication challenges and expenses associated with this approach such as heating steps to thermally round the sacrificial layer at the corners of the airbridge. Further, some sacrificial removal steps involve thermal treatment which adds more complexity and raises the fabrication cost of semiconductor devices, and also deteriorates the transistor characteristics after they have been optimized in association with the entire fabrication process. Thus, it has been a challenge in the prior art to produce an airbridge having a wide wiring layer while maintaining the required characteristics of the airbridge, such as strength and compatibility with the entire manufacturing process for semiconductor devices.

Most of the photoresist materials and polymers are used as a sacrificial layer are AZ type resists. Using these materials has many disadvantages such as:

good thickness uniformity with no retrograde profile is difficult to obtain when the resist is spun or deposited on the surface with via posts topology;

wide area airbridge structures need some gaps in the mask to aid the removal of the sacrificial layer, but complete removal of the resist is very difficult and always some resist will remain, for example, at the corners;

air can get trapped during the spin coat of the photoresist, producing air bubbles especially during the soft bake step;

the deposition of the airbridge's seed metal layer is performed under high vacuum, the sacrificial layer can shrink and damage the airbridge structure;

curved surface airbridge is preferred to prevent any sacrificial material from being left in the inner corners of the fabricated airbridge, as well as maintaining a good strength of the airbridge, but with resist/polymer type sacrificial layer, heating steps are required for rounding the sacrificial layer corners which add more complexity and costs in the fabrication process, and further, some sacrificial removal steps involve plasma treatment which adds more complexity and raises the fabrication cost of the semiconductor devices. The heating steps can easily deteriorate the transistor characteristics after they have been optimized in association with the entire fabrication process; and

air bridges which are resist/polymer-based require a minimum of two layers which adds more cost to the fabrication process since the resist/polymer coat is a single wafer process step.

### OBJECTS AND SUMMARY OF THE INVENTION

The following presents a simplified summary of some embodiments of the invention to provide a basic understanding of the invention. This summary is not an extensive overview of the invention. It is not intended to identify key/critical elements of the invention or to delineate the scope of the invention. Its sole purpose is to present some embodiments of the invention in a simplified form as a prelude to the more detailed description that is presented later.

The present invention is a manufacturing method to produce airbridge structures with a wide coverage area while maintaining good strength and stable characteristics of the semiconductor components and circuits on the substrate. The present invention overcomes the challenges and problems associated with the existing manufacturing approaches in the prior art. It is, therefore, an object of this invention to present a capable robust manufacturing approach for producing a wider airbridge structure while avoiding collapsing of the airbridge and degradation of the characteristics of the fabricated semiconductor components on the substrate as well as maintaining the compatibility with the entire manufacturing process of the semiconductor device.

The present invention provides a structure and manufacturing process for producing an airbridge for semiconductor devices and circuit applications. Moreover, the present invention is not limited to a specific semiconductor device and can be used in the production of any other standard semiconductor devices including MMIC (Monolithic Microwave Integrated Circuit).

In the present invention, magnesium oxide (MgO) is used to fabricate airbridges. The use of evaporated MgO allows for thicker and strong airbridge structures and increases the yield during the singulation of the fabricated devices and circuits. Using MgO as a sacrificial layer provides the flexibility for the sacrificial layer to be removed during the backend process, thereby avoiding any damage in the airbridge structures. In an alternative embodiment, some or all of the sacrificial layer of MgO can be retained in the airbridge structure, allowing for high density interconnects especially for ground connected interconnects. MgO is the only known low cost evaporated material, and MgO can be used without any limitations. MgO can be etched away very fast in compatible solutions such as diluted HCl and MICROSTRIP which are compatible with any steps of the entire fabrications of the integrated circuits. Further, MgO is evaporated at about 100° C. and is directly lifted off. As a solid material, MgO allows for multilevel air bridge structures.

In addition, MgO as an evaporated material can be completely removed without any residual. Due to its good properties such as high thermal conductivity, structure stability, MgO can be kept to add mechanical stability and to spread the heat away from the active areas of the fabricated circuits. Thus, the use of MgO increases the design options to serve multiple functions at the same time.

The present invention uses fewer photolithography steps and maintains very good integration compatibility with the other fabrication steps. MgO etches very fast in diluted HCl. For example, 30 seconds are enough to completely remove up to 3 micrometers of MgO. Moreover, substances commercially known as “MICROSTRIP 5002”, commercially available from “FUJIFILM ELECTRONIC MATERIALS U.S.A., INC.”, can be used as a low-cost alternative to diluted HCl, which allows for standard fabrication waste disposal and collection methods, lower toxicity and safer use, and etches MgO with an etch rate similar to the diluted HCl.

In the present invention, releasing the requirements of using a resist-based sacrificial layer has many advantages, including: (a) no thermal treatment is required for a round corner profile to promote the removal of the sacrificial layer; (b) no damage in the seed layer occurs since MgO does not shrink when depositing the metal seed layer; and (c) access to alignment marks after seed layer is no longer required, hence some lithography steps are eliminated. In addition, the use of evaporated MgO allows for thicker and stronger airbridge structures and increases the yield during the singulation of the fabricated devices and circuits.

In one embodiment, the present invention is a fabrication method including: fabricating an electronic component on a substrate; depositing a sacrificial layer on the electronic component; depositing a wiring layer on the sacrificial layer; and finalizing the sacrificial layer. The step of finalizing includes etching the sacrificial layer to remove at least a portion of the sacrificial layer. Alternatively, the step of finalizing includes retaining at least a first portion of the sacrificial layer. The sacrificial layer is composed of magnesium oxide (MgO). The etching is performed by applying N-Methyl-2-pyrrolidone (NMP), hydrochloric acid (HCl), and/or MICROSTRIP 5002 to the sacrificial layer. At least a second portion of the sacrificial layer forms an airbridge.

In another embodiment, the present invention is a method for fabricating an airbridge including: fabricating an electronic component on a substrate; depositing a sacrificial layer on the electronic component, wherein the sacrificial layer is composed of magnesium oxide (MgO); depositing a wiring layer on the sacrificial layer; and forming the airbridge from at least a first portion of the sacrificial layer. The step of forming includes etching the sacrificial layer to remove at least a second portion of the sacrificial layer. The etching is performed by applying N-Methyl-2-pyrrolidone (NMP), hydrochloric acid (HCl), and/or MICROSTRIP 5002 to the sacrificial layer.

In a further embodiment, the present invention is an electronic device including: a substrate; an electronic component disposed on the substrate; a sacrificial layer disposed on the electronic component; a wiring layer disposed on the sacrificial layer; and an airbridge formed by removal of at least a first portion of the sacrificial layer. The airbridge is formed by etching the sacrificial layer to remove the at least a first portion of the sacrificial layer. Alternatively, the airbridge is formed by retaining at least a second portion of the sacrificial layer. The sacrificial layer is composed of magnesium oxide (MgO). The etching is performed by applying N-Methyl-2-pyrrolidone (NMP), hydrochloric acid (HCl), and/or MICROSTRIP 5002 to the sacrificial layer.

### BRIEF DESCRIPTION OF THE DRAWINGS

The foregoing summary, as well as the following detailed description of presently preferred embodiments of the invention, will be better understood when read in conjunction with the appended drawings. For the purpose of illustrating the invention, there are shown in the drawings embodiments which are presently preferred. It should be understood, however, that the invention is not limited to the precise arrangements and instrumentalities shown.

In the drawings:

FIG. 1A is a flowchart for a fabrication method of the present invention;

FIG. 1B is a flowchart for an alternative fabrication method of the present invention;

FIG. 2A illustrates a sectional view of a fabricated structure after a first step in FIG. 1A, along an X-X direction;

FIG. 2B illustrates a sectional view of a fabricated structure after the first step, along a Y-Y direction, taken along lines 2B-2B in FIG. 2A;

FIG. 3A illustrates a sectional view of a fabricated structure after a second step in FIG. 1A, along an X-X direction;

FIG. 3B illustrates a sectional view of a fabricated structure after the second step, along a Y-Y direction, taken along lines 3B-3B in FIG. 3A;

FIG. 4A illustrates a sectional view of a fabricated structure after a third step in FIG. 1A, along an X-X direction;

FIG. 4B illustrates a sectional view of a fabricated structure after the third step, along a Y-Y direction, taken along lines 4B-4B in FIG. 4A;

FIG. 5A illustrates a sectional view of a fabricated structure after a fourth step in FIG. 1A, along an X-X direction; and

FIG. 5B illustrates a sectional view of a fabricated structure after the fourth step, along a Y-Y direction, taken along lines 5B-5B in FIG. 5A.

To facilitate an understanding of the invention, identical reference numerals have been used, when appropriate, to designate the same or similar elements that are common to the figures. Further, unless stated otherwise, the features shown in the figures are not drawn to scale, but are shown for illustrative purposes only.

### DETAILED DESCRIPTION OF THE PREFERRED EMBODIMENTS

Certain terminology is used in the following description for convenience only and is not limiting. The article “a” is intended to include one or more items, and where only one item is intended the term “one” or similar language is used. Additionally, to assist in the description of the present invention, words such as top, bottom, upper, lower, front, rear, inner, outer, right and left may be used to describe the accompanying figures. The terminology includes the words above specifically mentioned, derivatives thereof, and words of similar import.

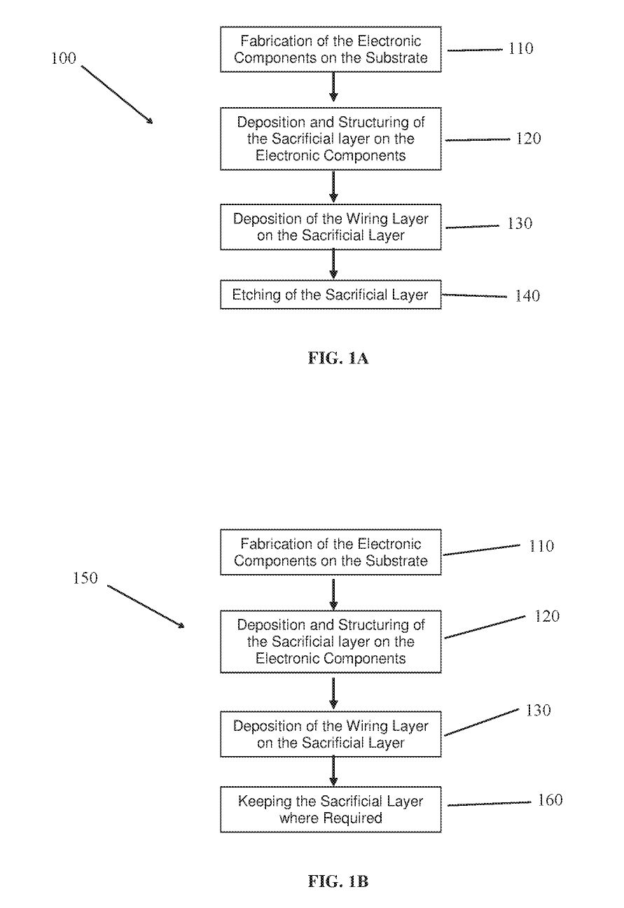

As shown in FIG. 1A, a flowchart of a fabrication sequence 100 of an airbridge of the present invention is shown using magnesium oxide (MgO) as a sacrificial layer. First, fabrication of the electronic components onto the substrate is performed in step 110. Then deposition and structuring of the sacrificial layer onto the electronic components is performed in step 120. Deposition of the wiring layer onto the sacrificial layer is then performed in step 130. Finally, etching of the sacrificial layer to remove the sacrificial layer and to leave a resulting airbridge is performed in step 140.

In an alternative embodiment of a fabrication sequence 150, as shown in FIG. 1B, the steps 110, 120, 130 are performed, but instead of etching the sacrificial layer to remove the sacrificial layer, the fabrication method may perform the step 160 of keeping the sacrificial layer if required and/or desired, such that a resulting airbridge with some or all of the sacrificial layer is formed. The fabrication process in FIGS. 1A-1B involves multiple steps which include, but are not limited to, photolithography, thin-film deposition, metal lift-off and etching.

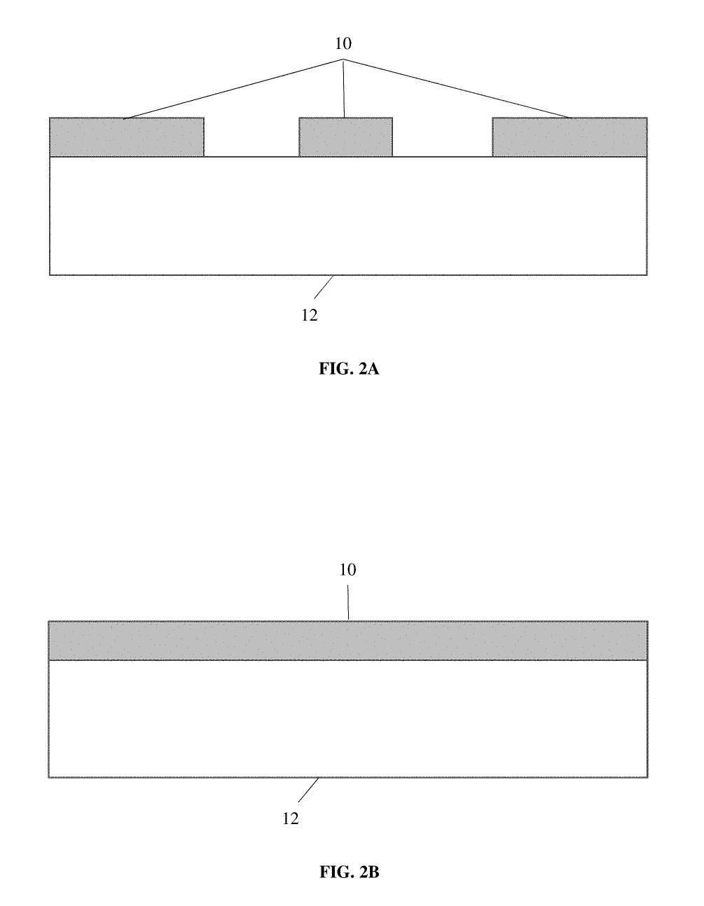

Referring to FIGS. 2A-5B, details of the manufacturing process are shown where X-X and Y-Y sectional views are presented for each structure at each step in the fabrication sequence. FIGS. 2A-2B illustrate a sectional view of electronic components 10 fabricated in step 110 on a substrate 12, such as a gallium arsenide (GaAs) or indium phosphide (InP) or silicon substrate or other substrate types. If required, transmission lines and/or via posts may be formed directly on the substrate as well as on top of the electronic elements 10 to interconnect some electronic components 10 or to form sub-circuits.

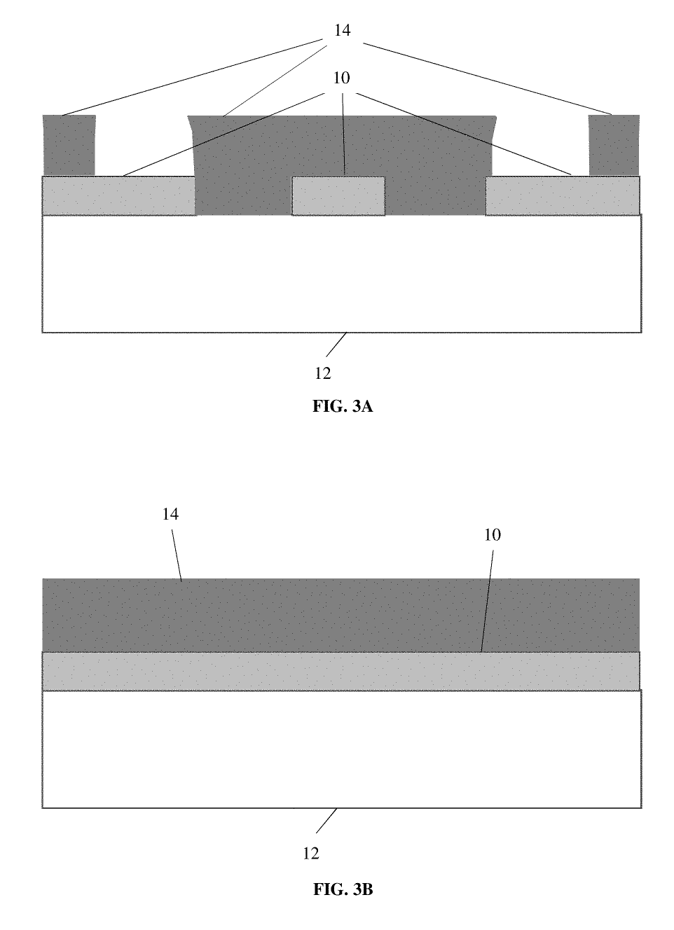

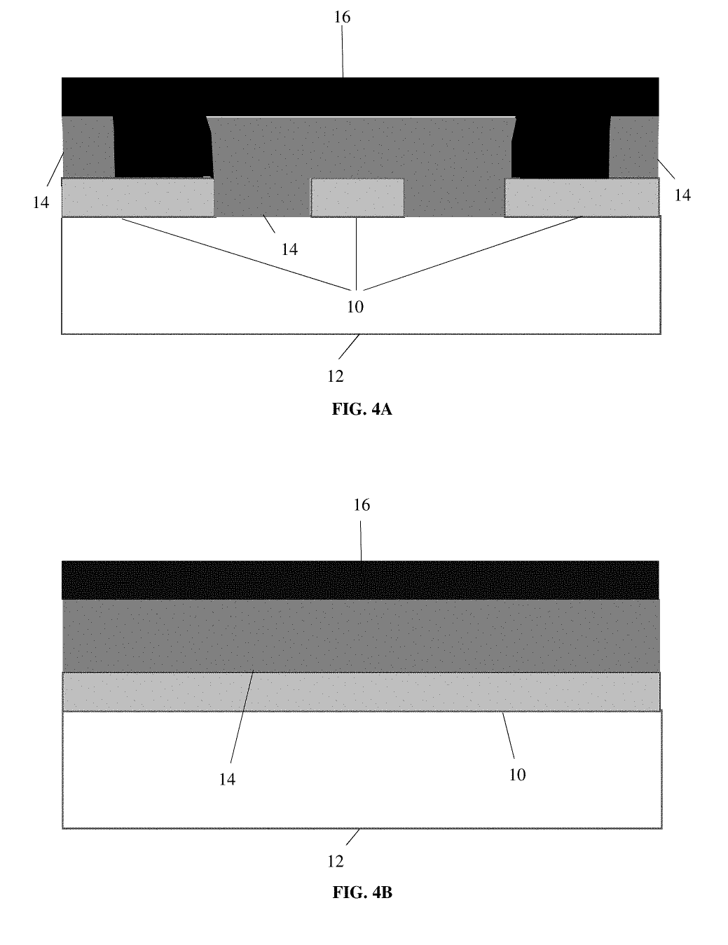

FIGS. 3A-3B show an embodiment of a sacrificial layer 14 made of MgO which is electron-beam evaporated, or otherwise deposited, on the electronic components to be connected which are to be located below the airbridge, in step 120. MgO is directly patterned using a lift off process, thus multi-level airbridges can be produced. As schematically shown in FIGS. 4A-4B, a metal layer 16 is deposited to interconnect the components on the substrate 12 and is formed by a lift-off process where the photoresist is structured with open areas on which the metal layer 16 is evaporated or otherwise deposited. For example, the metal layer 16 may typically be composed of gold, providing good conductivity to the metal layer 16 and the resulting airbridge.

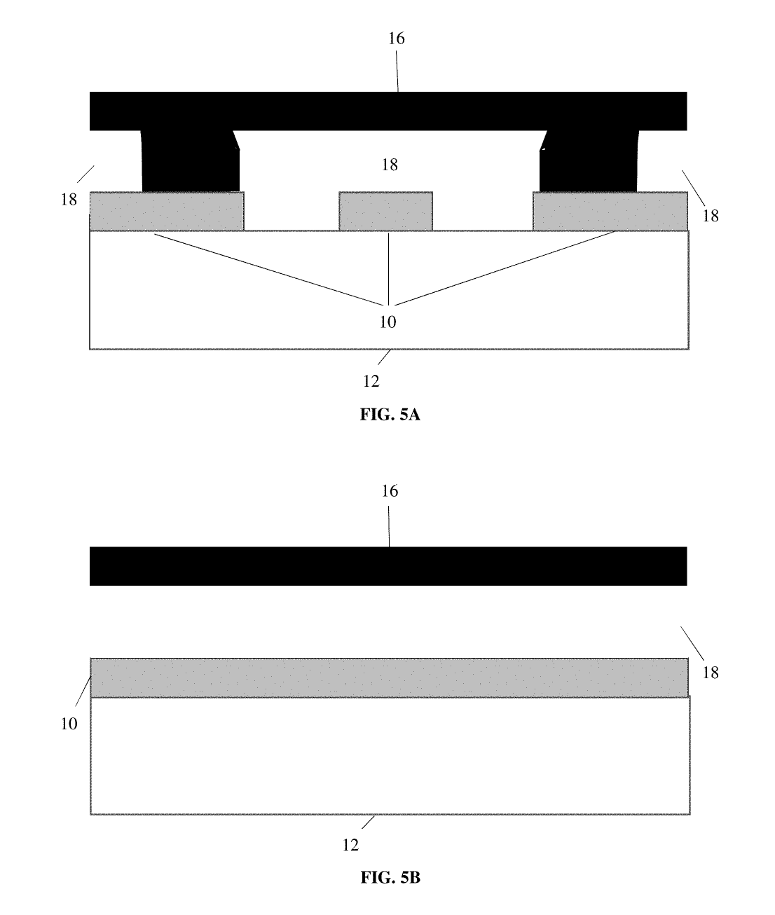

As shown in FIGS. 5A-5B, the fabricated structure is then treated in step 130 in an etching solution such as N-Methyl-2-pyrrolidone (NMP) to lift off the evaporated metal layer except the airbridge wiring layer 16. As shown in FIGS. 5A-5B, the sacrificial layer 14 of MgO can be easily removed by immersing the fabricated structure in a diluted hydrochloric (HCl) acid, such as HCl:DI with a water ratio of 1:15, thereby eliminating any typically required steps such as high temperature heat treatment or fluorinated ashing used in the prior art. Accordingly, the remaining metal layer 16 forms an airbridge with air gaps 18 remaining where the sacrificial layer 14 had been.

Alternatively, “MICROSTRIP 5002”, commercially available from “FUJIFILM ELECTRONIC MATERIALS U.S.A., INC.” can also be used as a low-cost solution to remove the MgO instead of using HCl. “MICROSTRIP 5002” has been determined to etch away MgO with a similar rate as diluted HCl. This substance is described in U.S. Pat. No. 5,780,406 A to Honda et al., which is incorporated herein in its entirety.

As shown in FIG. 1B and described herein, owing to the good insulation and mechanical properties of MgO, a portion or all of the sacrificial layer 14 of MgO, can be kept in step 160 to further strengthen the airbridge structures, avoiding any collapse issues during the backend processing of the structure.

The present invention may be embodied in other specific forms without departing from its spirit or essential characteristics. The described embodiments are to be considered in all respects only as illustrative and not restrictive. The scope of the invention is, therefore, indicated by claims rather than by the foregoing description. All changes which come within the meaning and range of equivalency of the claims are to be embraced within their scope.

What is claimed is:

1. A fabrication method comprising:
fabricating an electronic component on a substrate;
depositing a sacrificial layer on the electronic component;
depositing a wiring layer on the sacrificial layer; and
finalizing the sacrificial layer.

2. The fabrication method of claim 1, wherein the step of finalizing includes etching the sacrificial layer to remove at least a portion of the sacrificial layer.

3. The fabrication method of claim 1, wherein the step of finalizing includes retaining at least a first portion of the sacrificial layer.

4. The fabrication method of claim 1, wherein the sacrificial layer is composed of magnesium oxide (MgO).

5. The fabrication method of claim 2, wherein the etching is performed by applying N-Methyl-2-pyrrolidone (NMP) to the sacrificial layer.

6. The fabrication method of claim 2, wherein the etching is performed by applying hydrochloric acid (HCl) to the sacrificial layer.

7. The fabrication method of claim 2, wherein the etching is performed by applying MICROSTRIP 5002 to the sacrificial layer.

8. The fabrication method of claim 3, wherein at least a second portion of the sacrificial layer forms an airbridge.

9. A method for fabricating an airbridge comprising:
fabricating an electronic component on a substrate;
depositing a sacrificial layer on the electronic component, wherein the sacrificial layer is composed of magnesium oxide (MgO);
depositing a wiring layer on the sacrificial layer; and
forming the airbridge from at least a first portion of the sacrificial layer.

10. The fabrication method of claim 9, wherein the step of forming includes etching the sacrificial layer to remove at least a second portion of the sacrificial layer.

11. The fabrication method of claim 10, wherein the etching is performed by applying N-Methyl-2-pyrrolidone (NMP) to the sacrificial layer.

12. The fabrication method of claim 10, wherein the etching is performed by applying hydrochloric acid (HCl) to the sacrificial layer.

13. The fabrication method of claim 10, wherein the etching is performed by applying MICROSTRIP 5002 to the sacrificial layer.

14. An electronic device comprising:
a substrate;
an electronic component disposed on the substrate;
a sacrificial layer disposed on the electronic component;
a wiring layer disposed on the sacrificial layer; and
an airbridge formed by removal of at least a first portion of the sacrificial layer.

15. The electronic device of claim 14, wherein the airbridge is formed by etching the sacrificial layer to remove the at least a first portion of the sacrificial layer.

16. The electronic device of claim 14, wherein the airbridge is formed by retaining at least a second portion of the sacrificial layer.

17. The electronic device of claim 14, wherein the sacrificial layer is composed of magnesium oxide (MgO).

18. The electronic device of claim 15, wherein the etching is performed by applying N-Methyl-2-pyrrolidone (NMP) to the sacrificial layer.

19. The electronic device of claim 15, wherein the etching is performed by applying hydrochloric acid (HCl) to the sacrificial layer.

20. The electronic device of claim 15, wherein the etching is performed by applying MICROSTRIP 5002 to the sacrificial layer.
